(19) United States
(12) Patent Application Publication
(10) Pub. No.: US 2006/0186535 A1
(43) Pub. Date: Aug. 24, 2006

(54) Semi-conductor die mount assembly

(75) Inventors: Jay D. Baker, Dearborn, MI (US); Lawrence L. Kneisel, Novi, MI (US); Prathap A. Reddy, Farmington Hills, MI (US)

Correspondence Address: VISTEON, C/O BRINKS HOFER GILSON & LIONE, PO BOX 10395, CHICAGO, IL, 60610, US

(73) Assignee: Visteon Global Technologies, Inc.

(21) Appl. No.: 11/063,916

(22) Filed: Feb. 23, 2005

(51) Int. Cl. H01L 23/34

(52) U.S. Cl. 257/720

(57) ABSTRACT

A die mount assembly including a semiconductor die and die mount is provided. The semiconductor die may be a light emitting diode die that is attached to the die mount forming an electrical and thermal connection. The die mount includes a first set of pads and a second set of pads. A first pad of the first set of pads is connected to a second pad of the second set of pads through a plurality of vias. The vias comprise an electrically and thermally conductive material that connect the first pad to the second pad through a substrate.

### BACKGROUND

1. Field of the Invention

The present invention generally relates to a die mount assembly.

2. Description of Related Art

To dissipate heat, a III-V semiconductor die is often attached to a heat sink, such as a copper slug, with solder. As the semiconductor die heats, it transfers heat energy to the copper slug. The semiconductor die typically has a coefficient of thermal expansion of 4-6 ppm/C.°, while the copper slug has a coefficient of thermal expansion of 16-18 ppm/C°. Therefore, the slug expands at a higher rate than the semiconductor die imparting significant stresses in the solder material. These stresses contribute to the formation of voids in the solder material, which in turn decreases the effective cross sectional area of the solder material. The operating temperature of the die increases as the cross-sectional area for the heat transfer through the solder material decreases due to the voids. As a result, the increase of the die temperature may lead to early failure of the semiconductor die. Increasing the strength of the solder material results in the formation of cracks in the semiconductor die.

In some cases, the die is attached to a copper-invar-copper heat spreader. The copper-invar-copper heat spreader has a lower coefficient of thermal expansion than the copper slug alone. However, as the invar material has significantly lower thermal conductivity, 10 W/m-K° compared to the thermal conductivity of copper, 386 W/m-K°. Accordingly, the thermal conductivity of the copper-invar-copper slug will be significantly lower, leading to a higher operating temperature of the semiconductor die.

In view of the above, it is apparent that there exists a need for an improved die mount assembly.

### SUMMARY

In satisfying the above need, as well as overcoming the enumerated drawbacks and other limitations of the related art, the present invention provides a die mount assembly including a semiconductor die and a die mount.

The semiconductor die may be a light emitting diode die that is attached to the die mount to form an electrical and thermal connection. The die mount includes a first set of pads and a second set of pads. A first pad of the first set of pads is connected to a second pad of the second set of pads through a plurality of vias. The vias comprise an electrically and thermally conductive material that connect the first pad to the second pad through a substrate.

The substrate is formed of a material that is thermally conductive and electrically insulating. For example, the substrate may be made of silicon or aluminum nitride and may have a thermal coefficient of expansion between 3 and 6 ppm/C.° to closely match the coefficient of thermal expansion of the semiconductor die. The first pad, the second pad, and the plurality of vias may be comprised of copper. The semiconductor die may be attached to the die mount through soldering with a high temperature solder, or through a thermal compression bond. Although the substrate may be silicon, the substrate does not include active components and is therefore a non-heat generating substrate.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 is a top view of a die mount assembly in accordance with the present invention; and

FIG. 2 is a sectional side view, generally taken along line 2-2, of the die mount assembly seen in FIG. 1.

### DETAILED DESCRIPTION

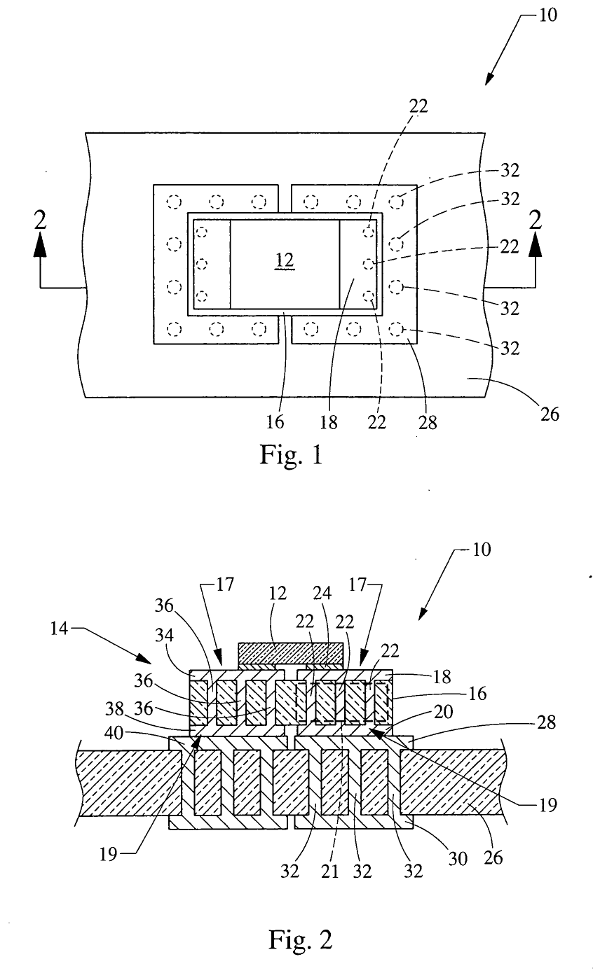

Referring to FIGS. 1 and 2, a die mount assembly embodying the principles of the present invention is illustrated therein and designated at 10. As its primary components, the die mount assembly 10 includes a semiconductor die 12 and a die mount 14.

The semiconductor die 12 may be a high powered die, such as a light emitting diode (LED). The semiconductor die 12 is attached (metallurgically or with epoxy) to the die mount 14. The die mount 14 includes a first set 17 of pads 18 and a second set 19 of pads 20. The first set 17 of pads (18, 34) are mounted on the top side of a substrate 16, while the second set 19 of pads (20, 38) are mounted on the bottom side of the substrate 16. A first and second pad (18, 20) are connected by a set 21 of vias 22. The vias 22 are configured to act as an electrical and thermal connection between the first and second pads 18, 20.

The semiconductor die 12 is connected to the first pad 18 through a solder bump 24. The solder bump 24 may be made of gold, gold-tin, solder alloy, silver epoxy, or other epoxy material. Further, the semiconductor die 12 may be attached to the first pad 18 through soldering. High temperature solder materials such as 10Sn-88Pb-2Ag, 95Pb-5Sn, or similar materials may be used. Alternatively, the semiconductor die 12 can be attached to the first pad 18 using a thermal compression bonding.

The first pad 18 and second pad 20, as well as, the vias 22 may all be made of copper. The vias 22 not only provide an electrical connection to the second pad 20, but also transfer heat efficiently from the semiconductor die 12 to the second pad 20 and the substrate 16. Further, each pad of the first set 17 of pads (18, 34) are also connected to a different pad of the second set 19 of pads (20, 38) through a separate set of vias. In addition, the die mount 10 may also have edge plating to provide electrical and thermal connection along the edge of the substrate 16.

The substrate 16 is made of a material having thermally conductive and electrically insulating properties. For example, the substrate 16 may be made of silicon, or aluminum nitride. If the substrate 16 was formed using silicon, the die mount 10 would match to the thermal coefficient of expansion of the semiconductor die 12 namely 3-6 ppm/C.°. Further, the substrate 16 is non-active and, therefore, non-heat generating.

As seen in the Figures, the substrate 16 extends beyond the edge of the semiconductor die 12 by a distance that is at least equal to the thickness of the substrate 16. As such, material is available to spread the thermal energy through the substrate 16 at an angle of at least 45° with respect to the area where the substrate 16 and semiconductor die 12 are attached.

The second pad 20 of the die mount 14 is metallurgically attached to a trace 28 on the circuit board 26 to form an electrical and thermal connection. The die mount 14 may be attached to the trace 28 by soldering, an epoxy, or thermal compression bonding. The first trace 28 carries a voltage from other components on the circuit board 26 or peripheral devices. As such, the circuit board 26 is configured to provide the voltage to the semiconductor die 12 through the vias 22. The first trace 28 is connected to a second trace 30 on the opposite side of the circuit board 26 through vias 32. The vias 32 may act as a thermal conduit but may also provide an electrical connection. The first trace 28, the second trace 30, and the vias 32 may be made of copper or other electrical and thermally conducting materials. The circuit board 26 may be made of any standard circuit board material.

In the case of an LED, the voltage supplied through vias 22 provides power to illuminate the LED. To complete the electric circuit, a second electrical connection is provided between the semiconductor die and the circuit board 26. Pad 34 of the first set 17 of pads is metalurgically bonded to the semiconductor die 12 via high temperature solder or thermo-compression bonding. A second set of vias 36 provide a thermally and electrically conductive path between pad 34 of the first set of pads 17 and pad 36 of the second set 19 of pads. Pad 36 is connected to trace 40 thereby providing a return path to the circuit board 26 and completing the power circuit.

As a person skilled in the art will readily appreciate, the above description is meant as an illustration of implementation of the principles this invention. This description is not intended to limit the scope or application of this invention in that the invention is susceptible to modification, variation and change, without departing from spirit of this invention, as defined in the following claims.

I/We claim:

1. A die mount assembly comprising:
a semiconductor die;
a die mount including a first and second pad, a plurality of vias, and a substrate, the first pad being attached to the semiconductor die, and the first pad being attached to the second pad through a plurality of vias, the plurality of vias comprising an electrically and thermally conductive material to dissipate heat and supply voltage to the semiconductor die.

2. The die mount assembly according to claim 1, wherein the substrate is formed of a material having a thermally conductive and electrically insulating material.

3. The die mount assembly according to claim 2, wherein the substrate has a coefficient of thermal expansion between 3 and 6 ppm/C°.

4. The die mount assembly according to claim 2, wherein the substrate is formed of silicon.

5. The die mount assembly according to claim 2, wherein the substrate is formed of aluminum nitride.

6. The die mount assembly according to claim 1, wherein the plurality of vias are formed of copper.

7. The die mount assembly according to claim 6, wherein the first and second pads are formed of copper.

8. The die mount assembly according to claim 1, wherein the semiconductor die is attached to the die mount through solder.

9. The die mount assembly according to claim 8, wherein the solder is a high temperature solder.

10. The die mount assembly according to claim 1, wherein the semiconductor die is attached to the die mount assembly through a thermal compression bond.

11. The die mount assembly according to claim 1, wherein the substrate is a non-heat generating substrate.

12. The die mount assembly according to claim 1, wherein the substrate is plated on an edge to connect the first and second pads.

13. A die mount assembly comprising:
a semiconductor die;
a die mount assembly including a first and second set of pads, a plurality of vias, and a substrate, each pad of the first set of pads being attached to the semiconductor die, and each pad of the first set of pads being attached to a pad of the second set of pads through at least one of the plurality of vias, the plurality of vias comprising an electrically and thermally conductive material to dissipate heat and supply voltage to the semiconductor die, wherein the substrate comprises a material having a thermally conductive and electrically insulating material.

14. The die mount assembly according to claim 13, wherein the substrate is formed of silicon.

15. The die mount assembly according to claim 13, wherein the substrate is formed of aluminum nitride.

16. The die mount assembly according to claim 13, wherein the substrate is a non-heat generating substrate.

17. A die mount assembly comprising:
a light emitting diode die;
a die mount including a first and second pad, a plurality of vias, and a substrate, the first pad being attached to the light emitting diode die, and the first pad being attached to the second pad through a plurality of vias, the plurality of vias comprising an electrically and thermally conductive material to dissipate heat and supply voltage to the light emitting diode die, wherein the substrate comprises a material having a thermally conductive and electrically insulating material.

18. The die mount assembly according to claim 17, wherein the substrate is formed of silicon.

19. The die mount assembly according to claim 17, wherein the substrate is formed of aluminum nitride.

20. The die mount assembly according to claim 17,.wherein the substrate is a non-heat generating substrate.
